(19) United States
(12) Patent Application Publication
(10) Pub. No.: US 2008/0038883 A1
(43) Pub. Date: Feb. 14, 2008

(54) Method for manufacturing semiconductor device utilizing recrystallized semiconductor film formed on an insulating film

(75) Inventor: Hiroyuki Shimada, Kofu-shi (JP)

Correspondence Address: OLIFF & BERRIDGE, PLC, P.O. BOX 320850, ALEXANDRIA, VA, 22320-4850, US

(73) Assignee: Seiko Epson Corporation, Tokyo (JP)

(21) Appl. No.: 11/905,934

(22) Filed: Oct. 5, 2007

Related U.S. Application Data
(62) Division of application No. 11/353,938, filed on Feb. 15, 2006.

(30) Foreign Application Priority Data
Mar. 2, 2005 (JP) 2005-057092
Oct. 27, 2005 (JP) 2005-312505

(51) Int. Cl. H01L 21/31; H01L 21/84

(52) U.S. Cl. 438/151; 438/759; 438/760; 257/E21.411; 257/E21.24; 257/E21.23

(57) ABSTRACT

A method for manufacturing a semiconductor device, the method comprising: forming a semiconductor device using a crystalline semiconductor film after the surface of the crystalline semiconductor film with two plane directions or more is treated by chemical mechanical polishing, wherein an alkali solution with a hydrogen ion concentration of PH 11.0 or less is used as a polishing liquid in the chemical mechanical polishing.

This is a Division of Application No. 11/353,938 filed Feb. 15, 2006. The disclosure of the prior application is hereby incorporated by reference herein in its entirety.

### BACKGROUND

1. Technical Field

The present invention relates to a method for manufacturing semiconductor devices, integrated circuits, electrooptics devices, and electronic apparatus.

2. Related Art

In order to improve the electrical characteristic of a thin film transistor (a semiconductor device) used for a liquid crystal display device or EL (electroluminescence) display device, a technique is proposed in which a semiconductor thin film is formed using a silicon film, the silicon film being substantially in a single crystal state. In this technique, after opening a micropore in an insulating film on a substrate and forming an amorphous silicon film on this insulating film as well as in the micropore, melt crystallization is carried out by irradiating a laser with a high energy density to this amorphous silicon film, thereby forming a crystal grain with a large grain diameter, the grain diameter being approximately several μm centering on the micropore.

“Single Crystal Thin Film Transistors”, IBM TECHNICAL DISCLOSURE BULLETIN August 1993, pp 257-258 is an example of related art.

In the case where a semiconductor film containing crystal grains with a large grain size is formed by the above-described method, the flatness of the surface of the semiconductor film tends to be not excellent. Especially when the micropores are arranged in relatively close proximity, because the crystal growth will progress centering on each of the adjoining micropores and collide to each other, the boundary (the grain boundary) between the crystal grains will rise and the flatness of the semiconductor film surface will be degraded.

Then, Chemical Mechanical Polishing (CMP) using an alkaline polishing liquid may be carried out to the semiconductor film surface to planarize.

Incidentally, in the case where a polished object is a crystalline one, the polishing speed in carrying out CMP depends on the crystal orientation thereof. However, a silicon semiconductor film surface (a crystalline semiconductor film) containing a crystal grain with a large grain diameter has a plurality of crystal orientations (plane directions), and a difference occurs in the polishing amount depending on this crystal orientation. Therefore, the surface of the silicon semiconductor film after the CMP results in a very rough state.

In this way, if the flatness of the silicon semiconductor film surface be degraded, the characteristic (the mobility) of the thin film transistor would be degraded due to the fact that when a thin film transistor (a semiconductor device) with a structure (a top gate type structure), in which a channel region is formed in the top face side of the silicon semiconductor film, the interface condition between the silicon semiconductor film and the gate insulating film formed on the upper side thereof will not be excellent.

### SUMMARY

An advantage of the invention is to provide a manufacturing method of a semiconductor device, the method capable of planarizing, when carrying out chemical mechanical polishing to a crystalline semiconductor film surface of which crystal orientation is not uniform, the crystalline semiconductor film, thereby improving the characteristic of the semiconductor device, and integrated circuits obtained by this manufacturing method, electrooptics devices, and electronic apparatuses.

According to an aspect of the invention, a method for manufacturing a semiconductor device, the method includes a step in which after the surface of a crystalline semiconductor film with two plane directions or more is treated by chemical mechanical polishing, a semiconductor device is formed using the crystalline semiconductor film, wherein an alkali solution with a hydrogen ion concentration of PH 11.0 or less is used as a polishing liquid in the chemical mechanical polishing.

According to the method for manufacturing the semiconductor device of the invention, the chemical mechanical polishing treatment (CMP) is carried out to a crystalline semiconductor film having two plane directions or more, the flatness of the surface thereof being low, such as a single crystal silicon film formed, for example, by melt crystallization, or a polycrystal film crystallized by laser annealing.

Here, by using an alkali solution with a hydrogen ion concentration of PH 11.0 or less as a polishing liquid, the surface roughness of the crystalline semiconductor film after CMP treatment can be set to 3.5 nm to 4.0 nm or less like an experiment example (refer to FIG. 2) described later. In the crystalline semiconductor film with such surface roughness, degradation of the transistor characteristic (electron mobility) is alleviated as compared with the conventional CMP treatment.

Accordingly, even if the CMP treatment is carried out to the surface of a crystalline semiconductor film having two plane directions or more, the surface roughness occurred in the surface of this crystalline semiconductor film will not have an influence on the characteristic of the semiconductor device, thereby enabling the characteristic of the semiconductor device to be improved due to the surface planarization.

According to another aspect of the invention, a method for manufacturing a semiconductor device, the method includes a step in which after the surface of a crystalline semiconductor film with two plane directions or more is treated by chemical mechanical polishing, a semiconductor device is formed using the crystalline semiconductor film, wherein an alkali solution with a hydrogen ion concentration of PH 9.0 or less is used as a polishing liquid in the chemical mechanical polishing.

According to the method for manufacturing the semiconductor device of the invention, the chemical mechanical polishing treatment (CMP) is carried out to a crystalline semiconductor film having two plane directions or more, the flatness of the surface thereof being low, such as a single crystal silicon film formed, for example, by melt crystallization, or a polycrystal film crystallized by laser annealing.

Here, by using an alkali solution with a hydrogen ion concentration of PH 9.0 or less as a polishing liquid, the surface roughness of the crystalline semiconductor film after the CMP treatment can be set to 1 nm or less like an experiment example (refer to FIG. 2) described later. Moreover, in the case where the surface roughness of the crystalline semiconductor film is 1 nm or less, thin film transistors (semiconductor devices) formed from this crystalline semiconductor film will have an enhanced transistor characteristic (electron mobility.)

Accordingly, even if CMP treatment is carried out to the surface of a crystalline semiconductor film having two plane directions or more, the surface roughness occurred in the surface of this crystalline semiconductor film does not have an influence on the characteristic of the semiconductor device, thereby enabling the characteristic of the semiconductor device to be improved due to the surface planarization.

In the above manufacturing method of the semiconductor device, it is preferable that the treatment be planarization or reduction in film thickness of the crystalline semiconductor film.

With this treatment, a flat and thin crystalline semiconductor film can be obtained and an excellent semiconductor device can be formed.

In the above manufacturing method of the semiconductor device, it is preferable that the crystalline semiconductor film be a single crystal silicon film that is formed, after a micropore is formed in an insulating film formed on a substrate and a non-single crystal silicon film is film-formed in this micropore as well as on the insulating film, by melt crystallizing this non-single crystal silicon film, the single crystal silicon film having the micropore substantially in the center thereof.

Here, the surface of the single crystal silicon film obtained by melt crystallization is the one having two plane directions or more and a low flatness due to the fact that the boundary (the grain boundary) between the crystal grains rises. Then, if the invention is adopted, it is possible to reduce the interface roughness and improve the characteristic of the semiconductor device by carrying out the chemical mechanical polishing treatment as described above, thereby planarizing the single crystal silicon film.

At this time, it is preferable that the film formation be carried out onto the insulating film so that the film thickness of the non-single crystal silicon film is 100 nm or more.

In this manner, it is possible to film-form thickly as to enlarge in grain size the crystal grain obtained by melt crystallization, and the single crystal silicon film can be reduced in film thickness to a desired film thickness by a subsequent chemical mechanical polishing treatment. In other words, it is possible to manufacture high-performance TFT devices with excellent crystallinity and excellent punch-through tolerance.

According to another aspect of the invention, an integrated circuit comprises the semiconductor device manufactured by the above method for manufacturing the semiconductor device.

Because the integrated circuit of the invention comprises semiconductor devices having excellent characteristic, the semiconductor devices being formed from a flat crystalline semiconductor film, the integrated circuit will be a reliable one.

According to another aspect of the invention, an electrooptics device comprises the integrated circuit described above.

Because the electrooptics device of the invention comprises integrated circuits composed of semiconductor devices with excellent characteristic, the electrooptics device will be a reliable one.

According to another aspect of the invention, an electronic apparatus comprises the electrooptics device described above.

Because the electronic apparatus of the invention comprises the reliable electrooptics device, the electronic apparatus provided with this also will be a highly reliable one.

### BRIEF DESCRIPTION OF THE DRAWINGS

The invention will be described with reference to the accompanying drawings, wherein like numbers refer to like elements.

FIG. 1 is a view explaining a manufacturing method of a semiconductor film.

FIG. 2 is a graph based on an experiment showing a relationship between a polishing liquid and a crystalline silicon film.

FIG. 3 is a view explaining an element formation step.

FIG. 4 is a view showing a connection diagram of an electrooptics device.

FIG. 5 shows views explaining specific examples of electronic apparatuses comprising the electrooptics device.

### DESCRIPTION OF THE EMBODIMENTS

Hereinafter, embodiments of the invention will be described with reference to the accompanying drawings.

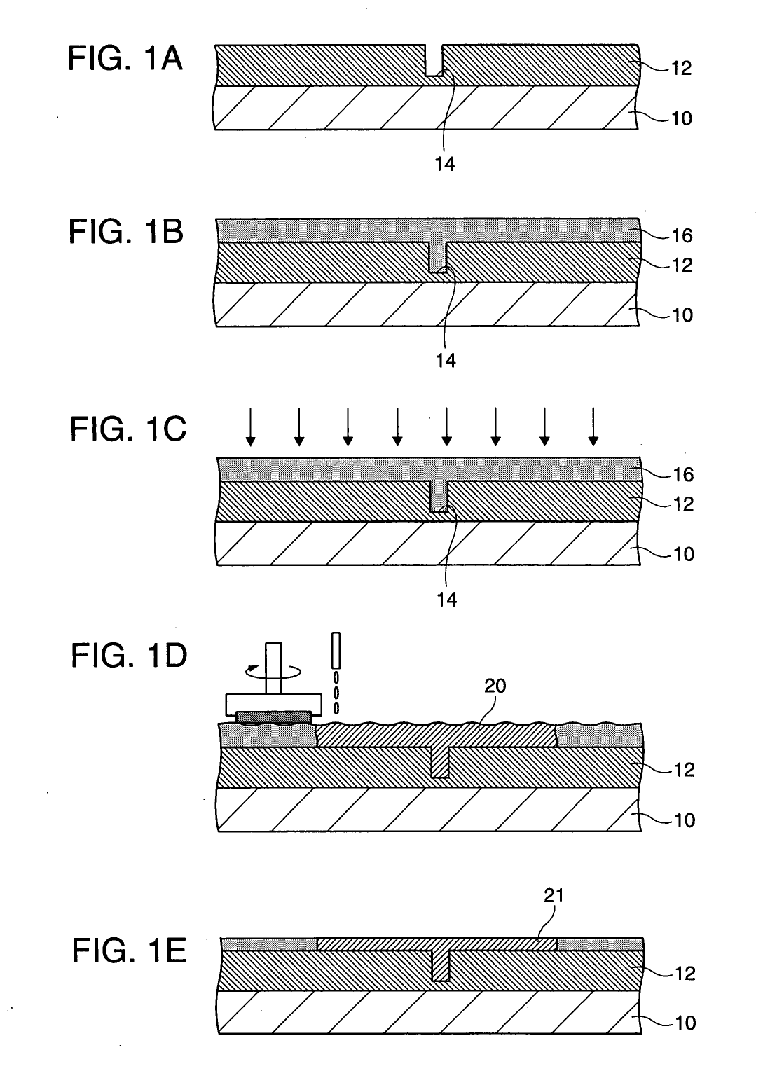

FIG. 1 is a view explaining a manufacturing method of a crystalline semiconductor film in this embodiment. In addition, the semiconductor device in the invention refers to devices in general that are formed using the crystalline semiconductor film obtained with a manufacturing method described later, and includes transistors, diodes, resistors, inductors, capacitors, other active elements, or passive elements.

Micropore Formation Step

First, a silicon oxide film 12 as an insulating film is formed on a substrate 10. As the method for forming the silicon oxide film 12 onto the substrate 10, there are listed a plasma enhanced chemical vapor deposition method (PECVD method) and a low pressure chemical vapor deposition method (LPCVD method), or a physical vapor deposition method such as a sputtering method. For example, with the PECVD method, the silicon oxide film 12 in thickness of several hundreds nm can be formed. Next, as shown in FIG. 1A, a micropore 14 is formed at a predetermined position of the silicon oxide film 12. For example, by carrying out a photolithography step and an etching step, the micropore 14 with a circular section can be opened at a predetermined position in a plane of the silicon oxide film 12. As the etching method, a reactive ion etching using plasma of CHF3 gas or the like is listed, for example.

Here, the micropore 14 plays a role of advancing, with priority, a crystal growth using one crystalline nucleus as the seed, in a melt crystallization step described later, and the micropore 14 is sometimes called a “grain filter”. Although it is suitable that this micropore 14 be formed, for example, in a cylinder shape, this micropore 14 may be formed in a shape other than the cylindrical shape (for example, a cone shape, prism shape, and pyramid shape, or the like). Moreover, the micropore 14 may be formed by forming a pore with a relatively large diameter (for example, approximately 500 nm) and thereafter, depositing a new insulating film (a silicon oxide film, in this example) across the substrate, thereby narrowing the diameter of the pore.

Film Formation Step

Next, as shown in FIG. 1B, amorphous silicon film (a non-single crystal silicon film) 16 is formed in the micropore 14 as well as on the silicon oxide film 12. The amorphous silicon film 16 may be formed with a PECVD method, a LPCVD method, an atmospheric pressure chemical vapor deposition method (an APCVD method), a sputtering method, or the like. In addition, in this step, as the non-single crystal semiconductor film, a polycrystal silicon film in place of the amorphous silicon film may be formed. In this step, it is desirable to film-form relatively thick as to attain substantially an increase in grain-size of the crystal grain, which is obtained by melt crystallization. More specifically, it is suitable to form the amorphous silicon film 16 in the film thickness of 150 nm or more.

Melt Crystallization Step

Next, as shown in FIG. 1C, laser is irradiated to the amorphous silicon film 16 to melt crystallize the amorphous silicon film 16. For example, it is suitable that the laser irradiation be carried out using XeCl pulse excimer laser (with a wavelength of 0.8 nm, and a pulse width of 30 n sec.) in an energy density of 0.4 to 1.5 J/cm². In addition, a solid state laser, a gas laser, or the like in place of the excimer laser may be used. Accordingly, a crystalline silicon film (a single crystal silicon film) 20 substantially in a single crystal state is formed as will be described later.

Here, most of the irradiated XeCl pulse excimer laser is absorbed in the vicinity of the surface of the amorphous silicon film 16. This is because the absorption coefficients of amorphous silicon and crystalline silicon at the wavelength (308 nm) of the XeCl pulse excimer laser are as large as 0.139 nm⁻¹ and 0.149 nm⁻¹, respectively. Moreover, because the silicon oxide film 12 is substantially transparent to the laser and does not absorb the energy of this laser, it will not melt by the laser irradiation. Accordingly, the amorphous silicon film 16 present in regions other than the micropore 14 will be completely melted across the region in the film thickness direction. Moreover, the amorphous silicon film 16 present in the micropore 14 will be melted in the upper part and not melted in the bottom part of the micropore 14 (in a partially melted condition).

The solidification of silicon after the laser irradiation starts first in the micropore 14, and then extends to the portion (the surface side portion), which is almost completely melted, of the amorphous silicon film 16. At this time, although several crystal grains occur in the vicinity of the bottom part of the micropore 14, only one crystal grain will reach the upper part (the opening) of the micropore 14 if making the dimensions (the diameter of circle, in this embodiment) of the cross section of the micropore 14 as large as one crystal grain or slightly smaller. Accordingly, in the portion almost completely melted, the crystal growth will progress with one crystal grain, which reached the upper part of the micropore 14 of the amorphous silicon film 16, being as a core, and as shown in FIG. 1D a crystalline silicon film 20 almost in a single crystal state is formed in the region substantially centering on the micropore 14. At this time, due to the influence from the crystallization, the flatness of the surface of the crystalline silicon film 20 will be degraded as illustrated.

Note that, in this embodiment, a “substantially single crystal” includes not only a state where the crystal grain is single, but also a state close thereto, i.e., a case where even if a plurality of crystals are combined, the number thereof is small, and the crystal grain is provided with the characteristic equivalent, from the viewpoint of the characteristic of semiconductor thin film, to that of the semiconductor thin film formed almost from a single crystal. This crystalline silicon film 20 will provide an effect that there are few defects therein, and in terms of the electrical characteristic of the semiconductor film, the trapping-level density near the center of the forbidden-band in the energy band is reduced. Moreover, because it is assumed that there is substantially no grain boundary, an effect capable of greatly decreasing the barrier when carriers, such as electrons and holes, flow is obtained. If this crystalline silicon film 20 is used for active layers (a source/drain region, and a channel formation region) of the thin film transistor (the semiconductor device) in a way described later, this crystalline silicon film 20 will be an excellent thin film transistor with a low off-state current value and a high mobility.

The flatness of the surface of the crystalline silicon film 20 substantially in a single crystal state is low as described above. Especially in the case where the micropores 14 are arranged relatively close to each other, because the crystal growth progresses centering on each of the adjoining micropores 14 and collides to each other, the boundary (the grain boundary) between the crystal grains will rise and the flatness in the surface of the crystalline silicon film 20 will decrease further.

Then, by planarizing the surface of the crystalline silicon film 20 with CMP (chemical mechanical polishing), a flat crystalline silicon film described later can be obtained.

Hereinafter, the steps for planarizing the surface of the crystalline silicon film 20 with CMP (chemical mechanical polishing) will be described.

### EXPERIMENT EXAMPLE

The present inventor carried out experiment regarding the influence that the surface roughness of the crystalline silicon film 20 has on the electron mobility, and the influence that the hydrogen ion concentration (PH) of a polishing liquid used in the CMP method has on the surface roughness of the crystalline silicon film 20. Then, this experiment example will be shown hereinafter.

There are two plane directions or more in the surface of the crystalline silicon film 20, i.e., the crystal orientation is not uniform. Therefore, if CMP treatment is carried out to the surface of this crystalline silicon film 20 using an alkaline polishing liquid (a slurry), which does not satisfy the conditions described later, a difference will occur in the polishing speed depending on the crystal orientation, and the surface roughness of the crystalline silicon film 20 will increase. In addition, the polishing liquid described above is the one made by dispersing a polishing agent, such as silica particles, into an alkali solution of an ammonia system or an amine system.

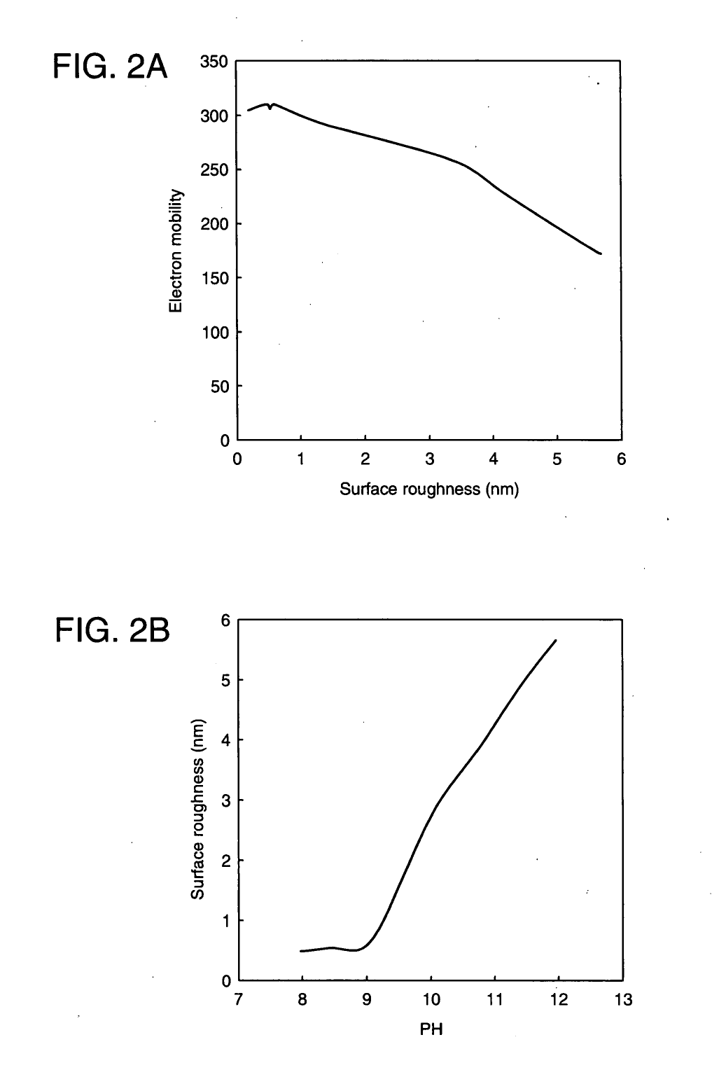

FIG. 2A is a graph showing a relationship between the surface roughness (the surface roughness) of the crystalline silicon film 20 after the CMP treatment, and electron mobility, and the horizontal axis shows the surface roughness and the vertical axis shows the electron mobility. In addition, the electron mobility on the vertical axis shows a relative value.

As shown in FIG. 2A, as the surface roughness of the crystalline silicon film 20 increases, the electron mobility will decrease. Then, the characteristic of the thin film transistor, which is formed using the crystalline silicon film 20 in the step described later, will be degraded.

The present inventor confirmed with the experiment that the hydrogen ion concentration (PH) in the polishing liquid has influence on the surface roughness after the polishing of the crystalline silicon film 20. FIG. 2B is a graph showing a relationship between the hydrogen ion concentration (PH) of the polishing liquid, and the surface roughness (the surface roughness) of the crystalline silicon film 20.

In addition, CMP was carried out under the experiment conditions of the pressure bar pressure on wafer of 30000 Pa, the rotational frequency of 70 rotation/minutes, the polishing liquid supply of 200 ml/min in 50 seconds.

With the experiment under this condition, as shown in FIG. 2B, it has been confirmed that if the hydrogen ion concentration of the polishing liquid is PH 11.0 or less, the surface roughness of the crystalline silicon film 20 is 3.5 to 4.0 nm or less. In addition, in order to melt the crystalline silicon film 20, the polishing liquid needs to be alkaline. If the surface roughness in the crystalline silicon 20 after the CMP treatment is 3.5 to 4.0 nm or less as described above, from the graph shown in FIG. 2A approximately 80 percent of the electron mobility in the case where there is no surface roughness can be provided. Namely, if the hydrogen ion concentration of the polishing liquid is PH 11.0 or less, the degradation of electron mobility due to the CMP treatment can be suppressed to such a level that will not cause a problem in use for the thin film transistor.

As shown in FIG. 2B, it has been confirmed that especially in the case where the hydrogen ion concentration of the polishing liquid is PH 9 or less, the surface roughness of the crystalline silicon film 20 is 1 nm or less. In addition, in order to melt the crystalline silicon film 20, the polishing liquid needs to be alkaline. Namely, it is more preferable that an alkali solution of PH 9 or less be used as the polishing liquid.

If the surface roughness in the crystalline silicon film 20 after the CMP treatment is 1 nm or less, then from the graph shown in FIG. 2A the electron mobility becomes high. Accordingly, the characteristic of the thin film transistor to be formed using the crystalline silicon film 20, the crystalline silicon film being planarized after the polishing treatment with the CMP in a step described later, can be enhanced.

Accordingly, in this embodiment, a case will be described in which an alkaline polishing liquid with the hydrogen ion concentration of PH 9.0 or less is used in the CMP treatment.

Planarization Step

Again, back to FIG. 1 to describe, as shown in FIG. 1D, the surface of the crystalline silicon film 20 is planarized with the CMP. At this time, in order to smooth the surface of the crystalline silicon film 20 and reduce the leakage current in the vicinity of the substrate side, i.e., avoid a punch-through phenomenon, a treatment to reduce the film thickness of a relevant crystalline silicon film 20 is also carried out. More specifically, it is preferable that the polishing be carried out until the film thickness of the crystalline silicon film 20 becomes 50 nm or less.

Here, an example of the suitable conditions for carrying out the above CMP will be described.

For example, a pad made of flexible polyurethane, and a polishing liquid, in which a polishing agent such as silica particles is dispersed into an alkali solution, such as an ammonia system or an amine system, are combined to be used. As described above, this polishing liquid is an alkali solution with an hydrogen ion concentration of PH 9.0 or less.

Accordingly, by using the above polishing liquid, the surface roughness of the crystalline silicon film 20 will be 1 nm or less when planarizing the crystalline silicon film 20 with the CMP treatment.

Accordingly, as shown in FIG. 1E, a high quality flat crystalline silicon film 21 is obtained, which is excellent in the surface flatness with the surface roughness of 1 nm or less, and which can also attain miniaturization of elements due to the reduction in film thickness.

Element Formation Step

Next, taking a thin film transistor (a semiconductor device) as an example, a step will be described in which a semiconductor device is formed using the flat crystalline silicon film 21 manufactured with the above-described manufacturing method.

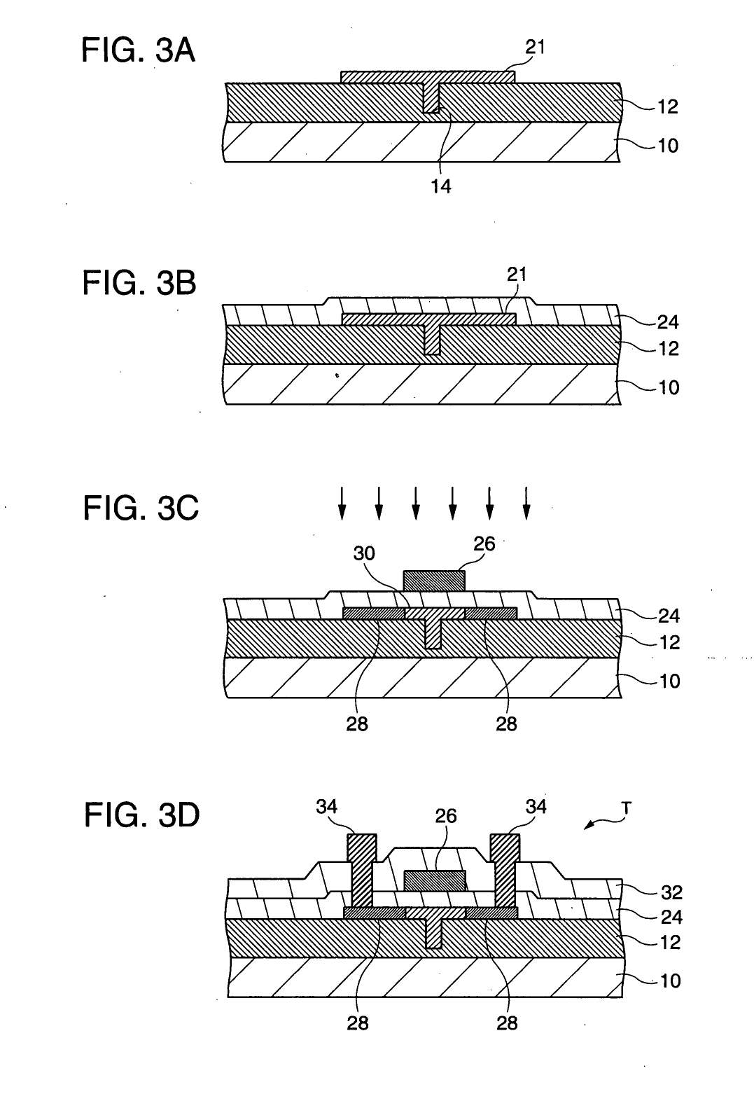

FIG. 3 is a view explaining an element formation step.

First, as shown in FIG. 3A, patterning of the flat crystalline silicon film 21 is carried out to remove portions to be unnecessary for the formation of the thin film transistor and to shape. In addition, the patterning may be carried out as to include a plurality of flat crystalline silicon films 21 formed adjacently.

Next, as shown in FIG. 3B, a second silicon oxide film 24 is formed on the silicon oxide film 12 and flat crystalline silicon film 21. For example, the second silicon oxide film 24 may be formed with an electron cyclotron resonance PECVD method (an ECR-CVD method) or a PECVD method. Needless to say, a direct oxidizing method by means of high density plasma may be used. This second silicon oxide film 24 will function as a gate insulating film of the thin film transistor.

Next, as shown in FIG. 3C, after a metal thin film made of tantalum or aluminum is formed with a sputtering method, a gate electrode 26 is formed by patterning. Next, impurity ions to be donors or acceptors are implanted using this gate electrode 26 as a mask, thereby producing a source/drain region 28 and a channel formation region 30 in self-alignment with the gate electrode 26. In producing an NMOS transistor, for example, as the impurity element, phosphorus (P) is implanted into the source/drain region in an concentration of 1×10¹⁶ cm⁻². Then, the impurity element is activated by irradiating an XeCl excimer laser with an irradiation energy density of approximately 400 mJ/cm², or by heat treating at the temperature of approximately 250° C. to 450° C.

Next, as shown in FIG. 3D, a third silicon oxide film 32 is formed in the upper face of the second silicon oxide film 24 and gate electrode 26. For example, the third silicon oxide film 32 of approximately 500 nm is formed with a PECVD method. Next, contact holes extending to the source/drain region 28 are opened in the second and third silicon oxide films 24 and 32, and a source/drain electrode 34 is formed in the contact holes and in the peripheral portion of the contact holes on the third silicon oxide film 32. The source/drain electrode 34 may be formed depositing aluminum, for example, with a sputtering method. Moreover, a contact hole extending to the gate electrode 26 is opened in the third silicon oxide film 32 to form a terminal electrode for the gate electrode 26. In this way, a thin film transistor T as the semiconductor device concerning the invention can be produced.

In addition, in the example shown in FIG. 3, for convenience of description, the micropore 14 is illustrated as to be located just under the thin film transistor, however, it is also preferable that the formation position of the micropore 14 may be away from just under the thin film transistor T. In this case, in patterning the portions to be an active region 30 or the like of the thin film transistor T in the patterning step described in FIG. 3A, the formation position of the micropore 14 just needs to be away therefrom.

In this way, in this embodiment, by planarizing, with the CMP treatment, the surface of the crystalline silicon film 20 to be obtained by melt crystallization, the flat crystalline silicon film 21 with a highly flat surface, the surface roughness thereof being 1 nm or less, can be obtained. Therefore, by using this flat crystalline silicon film 21, it is possible to attain improvement in the characteristic of the semiconductor device (the thin film transistor T) due to the planarization of the surface. Note that, in this embodiment, the CMP treatment using an alkaline polishing liquid with especially PH 9.0 or less has been described, however, as described above, if CMP treatment is carried out using an alkaline polishing liquid with PH 11.0 or less, a flat crystalline silicon film with a high flatness sufficient in practical use can be formed.

Next, specific examples of an integrated circuit comprising the semiconductor device described above, an electrooptics device, and an electronic apparatus will be described.

In addition, the integrated circuit in the invention refers to a circuit (a chip) in which semiconductor devices, associated wirings, or the like are integrated and wired as to perform a certain function. Moreover, the electrooptics device in the invention refers to devices in general provided with an electrooptics element, the electrooptics element emitting light based on an electric action or changing the state of light from the outside, the electrooptics element being provided with the semiconductor device concerning the invention. The above electrooptics device includes both the electrooptics element that emits light itself, and the electrooptics element that controls passage of light from the outside. For example, the electrooptics element includes a liquid crystal device, an electrophoresis element having a dispersion medium into which electrophoresis particles are dispersed, an EL (electroluminescence) element, and an active matrix type display device provided with an electron emission element that strikes to a luminescence plate the electrons generated by application of an electric field, thereby emitting light.

Moreover, the electronic apparatus of the invention refers to apparatus in general which performs a certain function, the apparatus being provided with the semiconductor device concerning the invention, and the electronic apparatus comprises, for example, electrooptics devices and memories. Although the configuration thereof is not limited in particular, the electronic apparatus of the invention includes, for example, an IC card, a cellular phone, a video camera, a personal computer, a head-mounted display, a rear type or front type projector, and furthermore, a fax device with a display function, a view finder of a digital camera, a portable type TV, a DSP device, a PDA, an electronic notebook, a video billboard, a display for advertisement, and the like.

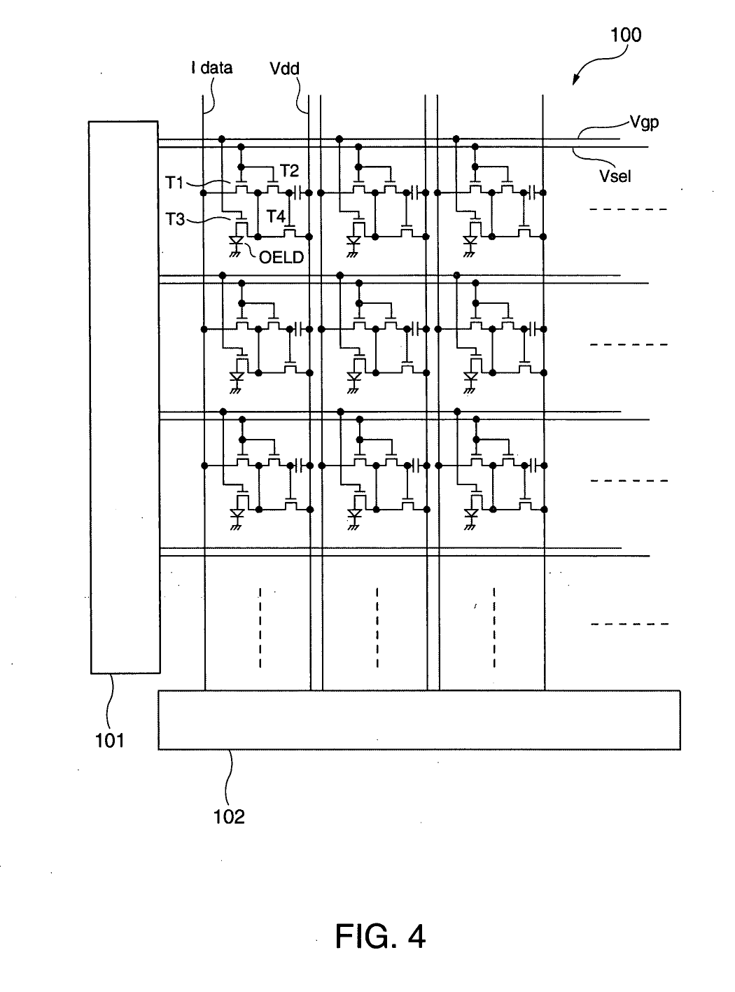

A connection diagram of an electrooptics device 100 is shown in FIG. 4. The electrooptics device (the display device) 100 of this embodiment comprises, in each pixel region, a luminescent layer OELD capable of emitting light based on electroluminescence effect, a storage capacitor that stores electric current for driving it, and semiconductor devices manufactured with the manufacturing method of the invention, i.e., thin film transistors T1 to T4, here. From a driver 101, a scanning line Vsel and a luminescence control line Vgp are supplied to each pixel region. From a driver 102, a data line Idata and a power supply line Vdd are supplied to each pixel region. By controlling the scanning line Vsel and data-line Idata, current programming for each pixel region is carried out, thereby making luminescence by the luminescent layer OELD controllable.

In addition, the driver circuit is an example of the circuit in the case where electroluminescence devices are used for the luminescence element, and other circuit configuration may be possible. Moreover, it is also suitable that the integrated circuits configuring each of the drivers 101 and 102 be formed from the semiconductor devices concerning the invention.

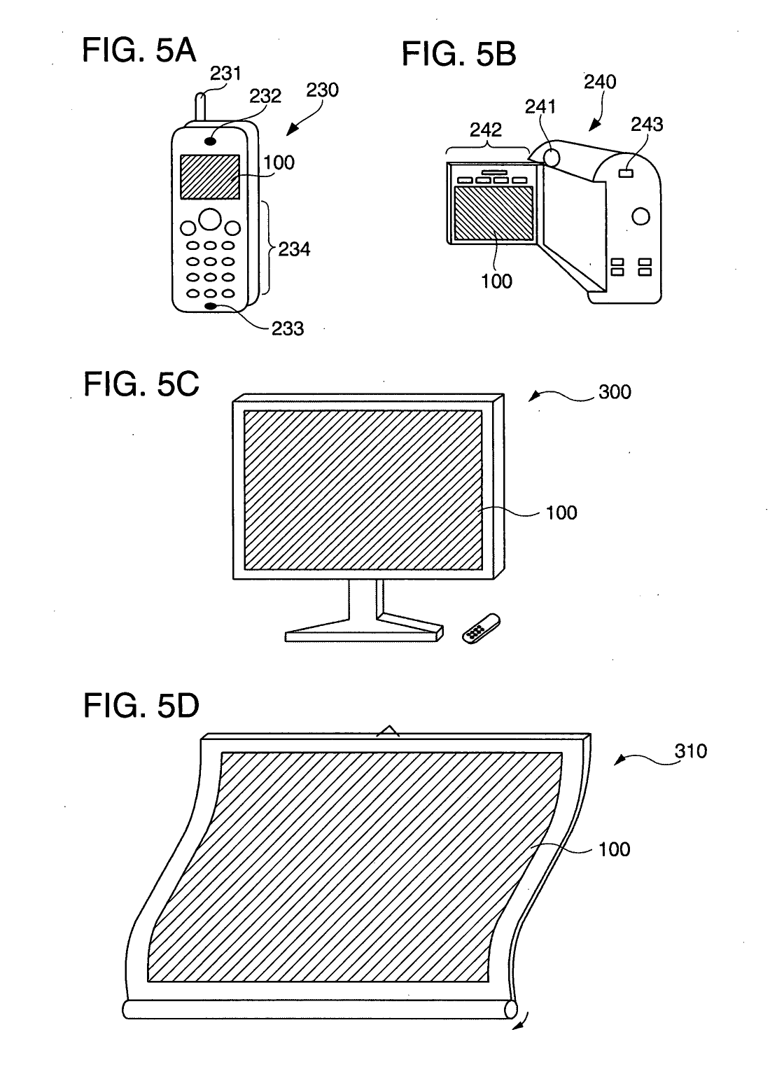

In FIG. 5, there are shown views explaining specific examples of the electronic apparatus comprising the electrooptics devices described above. FIG. 5A is an application example to a cellular phone, in which a cellular phone 230 concerned is provided with an antenna section 231, a voice output section 232, a voice input section 233, an operating section 234, and the electrooptics device 100 of the invention. In this way, the electrooptics device concerning the invention can be used as a display. FIG. 5B is an application example to a video camera, in which a video camera 240 concerned is provided with an image-receiving section 241, an operating section 242, a voice input section 243, and the electrooptics device 100 of the invention. FIG. 5C is an application example to a television, in which a television 300 concerned is provided with the electrooptics device 100 of the invention. In addition, the electrooptics device concerning the invention can be applied to a monitor device used for a personal computer or the like, in the same way. FIG. 5D is an application example to a roll-up type television, in which a roll-up type television 310 concerned is provided with the electrooptics device 100 of the invention. Moreover, the electronic apparatus is not limited thereto, and the invention can be applied to various kinds of electronic apparatuses having a display function. For example, in addition to these, the electronic apparatus includes a fax device with a display function, a view finder of a digital camera, a portable type TV, an electronic notebook, a video billboard, a display for advertisement, or the like. In addition, the semiconductor device concerning the invention can be applied independently also as a component of an electronic apparatus in addition to the cases where it is included in the above electronic apparatuses as a component of the electrooptics device.

In addition, various modification can be implemented within the scope of the contents of the invention without being limited to the each embodiment described above.

For example, although in the above-described embodiments a silicon film taken as an example of the semiconductor film has been described, the semiconductor film is not limited thereto. Moreover, although in the above-described embodiments a thin film transistor taken as an example of the semiconductor device to be formed using a crystalline semiconductor film has been described, the semiconductor device is not limited thereto, and other devices (for example, a thin film diode, or the like) may be formed.

Moreover, although in this embodiment there has been shown application examples regarding the single crystal silicon film obtained by melt crystallization, the invention can be applied similarly also to polycrystal silicon made with a general laser annealing method, thereby improving the semiconductor characteristic (electron mobility) of the semiconductor device obtained from this polycrystal silicon.

The entire disclosure of Japanese Patent Application Nos: 2005-057092, filed Mar. 2, 2005 and 2005-312505, filed Oct. 27, 2005 are expressly incorporated by reference herein.

What is claimed is:

1. A method for manufacturing a semiconductor device, the method comprising:
forming an insulating film on a substrate;
forming a micropore in the insulating film on the substrate;
depositing a film in the micropore and on the insulating film; and
planarizing a surface of the film,
the alkali solution whose pH is 11.0 or less being used of the planarizing of the surface of the film.

2. The method for manufacturing a semiconductor device according to claim 1,
the alkali solution having PH 9.0 or less.

3. The method for manufacturing a semiconductor device according to claim 1,
the treating of the film being carried out for a planarization or a reduction in a thickness of the film.

4. The method for manufacturing a semiconductor device according to claim 3,
a single crystal silicon film being formed by melting at least a part of a non-single crystal silicon film formed on an insulating film in which the micropore is formed.

5. The method for manufacturing a semiconductor device according to claim 4,
the non-single crystal silicon film being formed such that a thickness of the non-single crystal silicon film is 100 nm or more.

6. The method for manufacturing a semiconductor device according to claim 1,
the semiconductor device is a thin film transistor.

7. The method for manufacturing a semiconductor device according to claim 1,
the semiconductor device is a thin film diode.

8. The method for manufacturing a semiconductor device according to claim 1,
the film having two or more directions.

9. The method for manufacturing a semiconductor device according to claim 1,
the depositing the film is carried out by chemical vapor deposition.

10. The method for manufacturing a semiconductor device according to claim 1,
polishing the surface of the film is carried our by chemical mechanical polishing.

11. A method for manufacturing a semiconductor device, the method comprising:
forming an insulating film on a substrate;
forming a hole in the insulating film on the substrate;
depositing a film in the hole and on the insulating film; and
planarizing a surface of the film,
the alkali solution whose pH is 11.0 or less being used for the planarizing of the surface of the film.
